(19) United States
(12) Patent Application Publication
(10) Pub. No.: US 2011/0102988 A1
(43) Pub. Date: May 5, 2011

(54) MOUNTING STRUCTURE FOR AN ELECTRONIC COMPONENT AND AN ELECTRONIC DEVICE

(75) Inventor: Katsuyuki MATSUO, Hanno-shi (JP)

(73) Assignee: Casio Computer Co.; Ltd., Tokyo (JP)

(21) Appl. No.: 12/915,161

(22) Filed: Oct. 29, 2010

(30) Foreign Application Priority Data
Oct. 30, 2009 (JP) 2009-250211

(51) Int. Cl. H05K 5/02

(52) U.S. Cl. 361/679.01

(57) ABSTRACT

In a mounting structure for an electronic component which requires a supporting member and side surface bonding, the electronic component will be prevented from being detached from the supporting member even if subjected to additional weight from the exterior. The structure is provided with a substantially plate-shaped electronic component (12), and a supporting member (13) having an opening (13a) on a side surface for bonding and supporting the electronic component (12). The electronic component (12) is inserted into the opening (13a) from a front surface section side, and a back surface supporting section (13c) for supporting the electronic component (12) from a back surface section thereof is formed in the supporting member (13). The electronic component (12) is sealed to the back surface supporting section (13c) of the supporting member (13) by an adhesive (14). The supporting member (13) supports altogether the electronic component (12) and a flexible substrate (11).

### CROSS-REFERENCE TO RELATED APPLICATION

This application is based upon and claims the benefit of priority from the prior Japanese Patent Application No. 2009-250211, filed Oct. 30, 2009, the entire contents of which is incorporated herein by reference.

### BACKGROUND OF THE INVENTION

1. Field of the Invention

The present invention relates to a mounting structure for a substantially plate-shaped electronic component and an electronic device provided with an electronic component based on that mounting structure.

2. Description of the Related Art

In an electronic device mounted with an image sensor, such as a digital camera, a method is used in which an image sensor is primarily configured with a complementary metal-oxide semiconductor (CMOS) mounted on a flexible substrate, and the flexible substrate is bonded to a camera module.

In recent years, to obtain improvement in the positioning accuracy of an image sensor with such a mounting structure, a structure has been proposed in which a side surface section of an image sensor mounted on a flexible substrate is sealed to a metal plate by a resin adhesive, and the plate is fixed to a camera module with screws.

However, in conventional technology, a problem can be expected to occur considering that the image sensor is only bonded to the plate and the image sensor may become detached from the plate when the image sensor is subjected to a load from the camera module side due to an external impact.

In a mounting structure for an electronic component which requires a supporting member and bonding, an object of the present invention is to prevent the electronic component from being detached from the supporting member even if subjected to additional weight from the exterior.

### SUMMARY OF THE INVENTION

In accordance with one aspect of the present invention, there is provided a mounting structure for an electronic component comprising: a substantially plate-shaped electronic component; and a supporting member having an opening on a side surface section for bonding and supporting the substantially plate-shaped electronic component; wherein the substantially plate-shaped electronic component is inserted into the opening from a front surface section side, and a back surface supporting section for supporting the substantially plate-shaped electronic component from a back surface section thereof is formed in the supporting member.

In accordance with another aspect of the present invention, there is provided an electronic device having the above-described mounting structure.

The above and further novel features of the present invention will more fully appear from the following detailed description when the same is read in conjunction with the accompanying drawings. It is to be expressly understood, however, that the drawings are for the purpose of illustration only and are not intended as a definition of the limits of the invention.

### BRIEF DESCRIPTION OF THE DRAWINGS

FIG. 1 is a perspective diagram showing a configuration of an embodiment where the present invention has been applied to an electronic device, in which outer panels and the like of a camera has been attached to the electronic device;

FIG. 2 is a diagram showing the housing of the electronic device, in which the outer panels and the like in FIG. 1 have been removed;

FIG. 3 is an exploded diagram showing components of the housing in FIG. 2, and internal components thereof;

FIG. 4 is an enlarged view of the lens unit in FIG. 3 when viewed from the bottom surface side;

FIG. 5 is a vertical cross-sectional view of the bottom surface section of the lens unit in FIG. 4;

FIG. 6A is a perspective view of the supporting member in FIG. 4 when viewed from above;

FIG. 6B is a perspective view of the supporting member in FIG. 4 when viewed from below;

FIG. 7 is a perspective diagram showing the mounting of a substantially plate-shaped electronic component to the supporting member shown in FIG. 6A and FIG. 6B;

FIG. 8 is a diagram showing the positioning of the supporting member and the substantially plate-shaped electronic component in FIG. 7;

FIG. 9 is a diagram showing the bonding of the supporting member and the substantially plate-shaped electronic component in FIG. 8;

FIG. 10 is a diagram showing the bonding of the supporting member and a flexible substrate on the back surface of the substantially plate-shaped electronic component in FIG. 9;

FIG. 11 is a diagram showing the bonding of the supporting member and the flexible substrate on the back surface of the substantially plate-shaped electronic component in FIG. 10 when viewed from the reverse side;

FIG. 12 is a cross-sectional view taken along the arrow A-A line in FIG. 11;

FIG. 13 is a cross-sectional view taken along the arrow B-B line in FIG. 11;

FIG. 14 is a perspective diagram showing a variation example of a back surface supporting section; and

FIG. 15 is an enlarged view of the back surface supporting section in FIG. 14 when viewed from a different direction.

### DETAILED DESCRIPTION OF THE PREFERRED EMBODIMENTS

The present invention will hereinafter be described in detail with reference to the preferred embodiments shown in the accompanying drawings.

### Embodiment

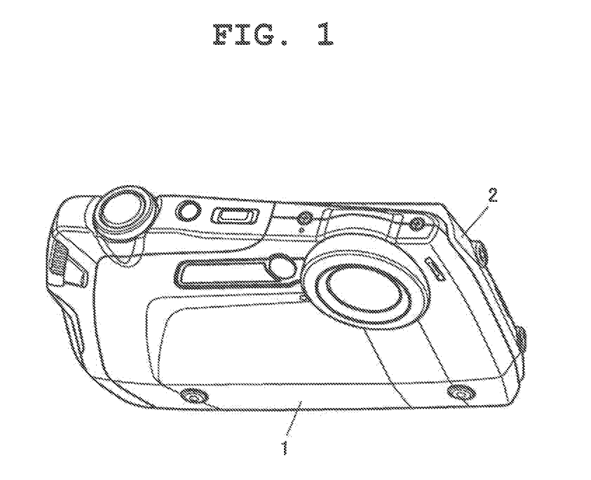

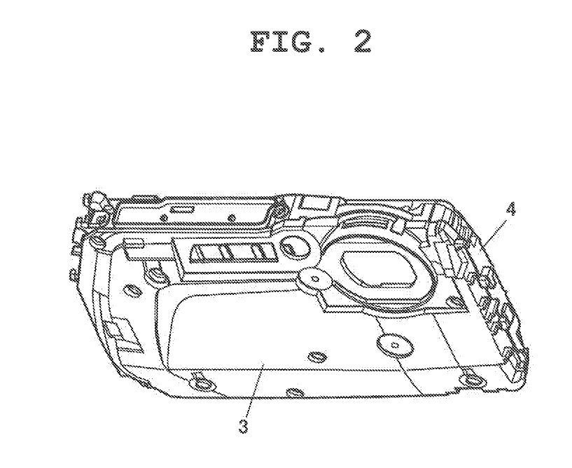

FIG. 1 and FIG. 2 show a camera for describing a configuration of an embodiment where the present invention has been applied to an electronic device. Reference numeral 1 represents a front panel, and reference numeral 2 represents a rear panel. In addition, reference numeral 3 represents a front case, and reference numeral 4 represents a rear case.

In the embodiment, the front case 3 and the rear case 4 are made of resin, and when the front panel 1, the rear panel 2, and the like shown in FIG. 1 that serve as the exterior of the camera are removed, a housing constituted by these cases and the like shown in FIG. 2 is exposed.

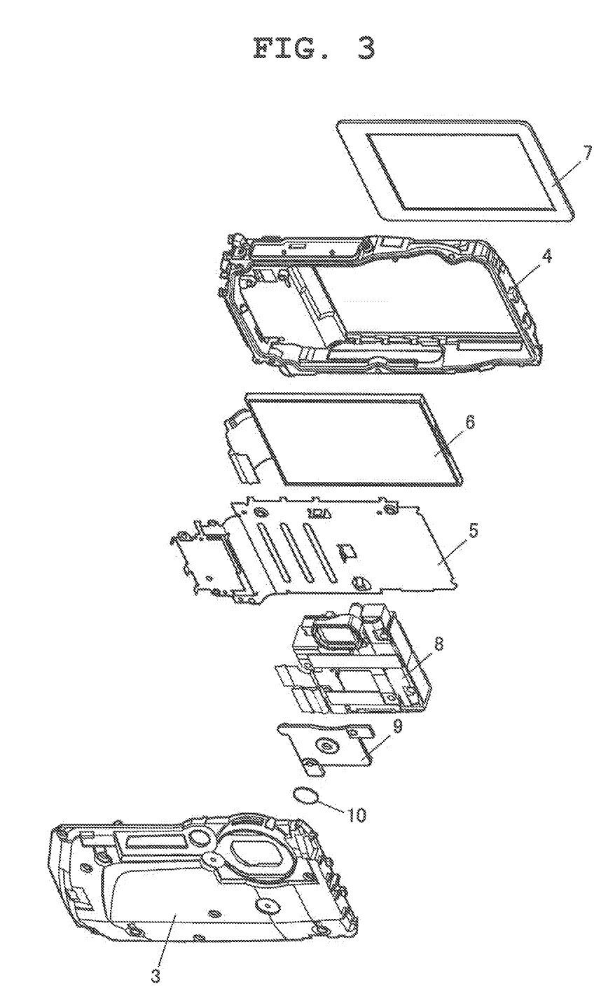

FIG. 3 is an exploded diagram showing components of the housing in FIG. 2, and internal components thereof. Reference numeral 5 represents a metal frame, and reference numeral 6 represents a liquid crystal display (LCD) unit. In addition, reference numeral 7 represents a display plate, and reference numeral 8 represents a lens unit. Moreover, reference numeral 9 represents a lens holder, and reference numeral 10 represents a porous film.

That is, the metal frame 5 and the LCD unit 6 are incorporated in the rear case 4, and the acrylic display plate 7 is attached on the outer surface of the rear case 4. The lens unit 8, which is a module where a lens group for capturing images is incorporated in a case, is housed between the metal frame 5 and the front case 3, and the elastomer lens holder 9 and the porous film 10 are provided between the lens unit 8 and the front case 3.

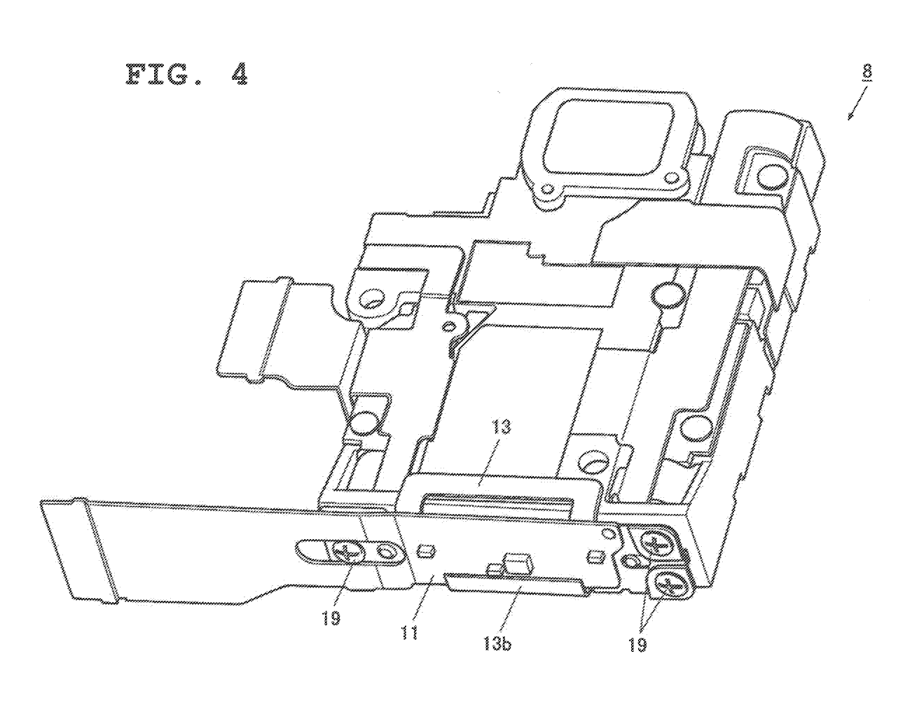

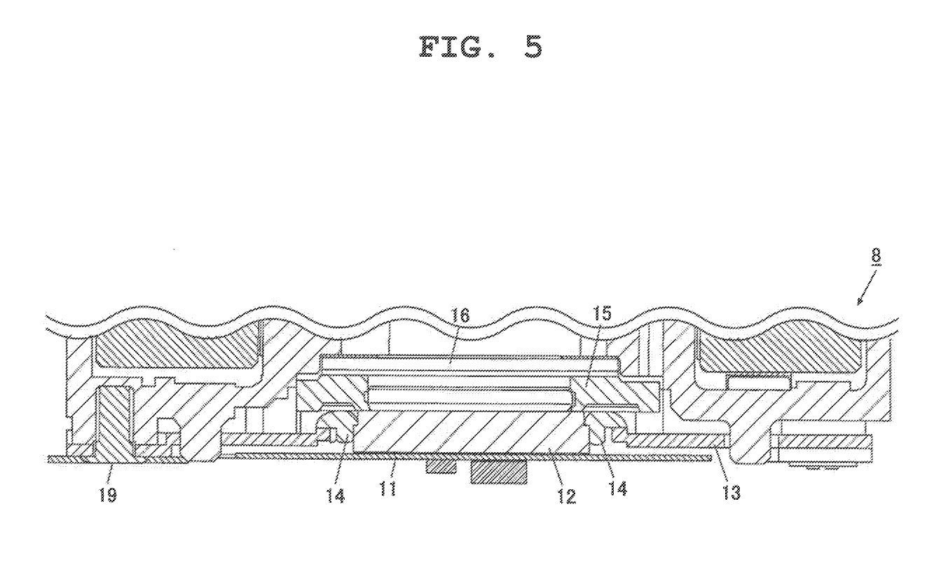

FIG. 4 is an enlarged view of the lens unit 8 when viewed from the bottom surface side, and FIG. 5 is a vertical cross-sectional view of the bottom surface section of the lens unit 8. Reference numeral 11 represents a flexible substrate, and reference numeral 12 represents an image sensor (electronic component). In addition, reference numeral 13 represents a plate (supporting member), and reference numeral 14 represents ultraviolet (UV) curing adhesive. Moreover, reference numeral 15 represents an elastic member, and reference numeral 16 represents an optical filter.

As shown in FIG. 4 and FIG. 5, the flexible substrate 11 is screwed and fixed on the bottom surface of the lens unit 8 by a plurality (three in FIG. 4) of screws 19, with the metal plate 13 therebetween. The substantially plate-shaped image sensor 12, which is constituted by a CMOS, is mounted on this flexible substrate 11, and the image sensor 12 and the flexible substrate 11 are supported altogether by the plate 13.

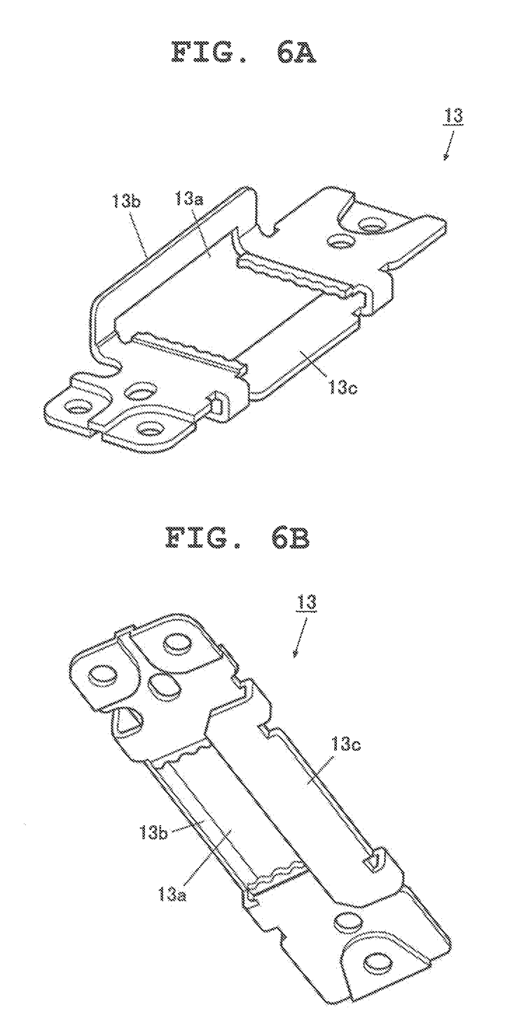

As shown in FIG. 6A and FIG. 6B, the plate 13 serves as a supporting member, which is integrally formed with an opening 13a therein for bonding and supporting the image sensor 12 to a side surface section of the plate 13, an erect section 13b bent upwards on one side section of the opening 13a and a back surface supporting section 13c bent downwards in a U-shape on the other side section of the opening 13a.

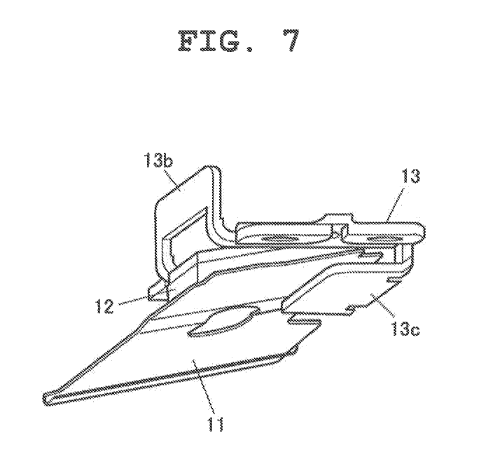

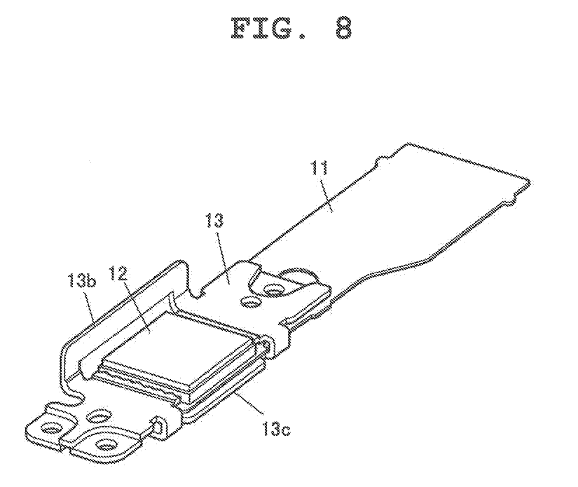

FIG. 7 shows the mounting of the image sensor 12 to the plate 13. As shown in FIG. 7, the image sensor 12 and the flexible substrate 11 are inserted altogether into the U-shaped section of the back surface supporting section 13c from below, at an angle to the bottom surface of the plate 13. As a result, as shown in FIG. 8, the image sensor 12 is positioned in the opening 13a of the plate 13.

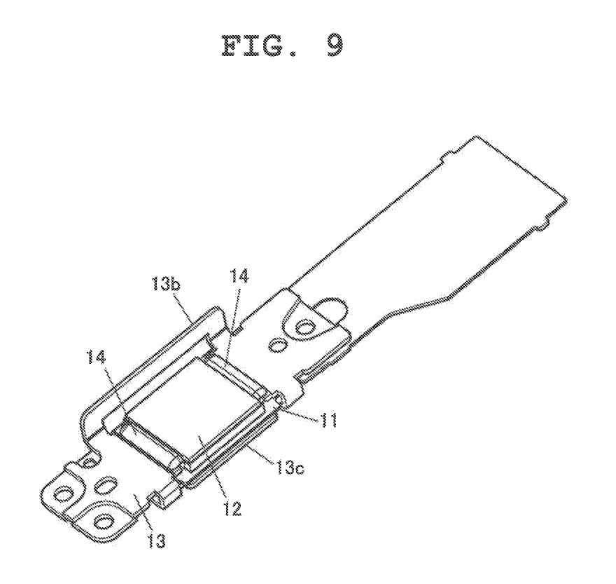

Next, as shown in FIG. 9, the UV curing adhesive 14, which hardens when irradiated with UV rays, is applied along both side sections of the opening 13a of the plate 13 and both side surface sections of the image sensor 12, and then irradiated with UV rays to be hardened.

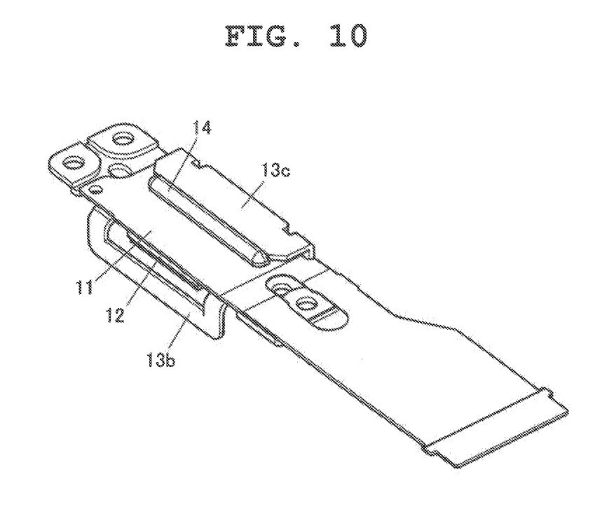

In addition, as shown in FIG. 10, the UV curing adhesive 14 is applied along the tip section of the back surface supporting section 13c of the plate 13, filling the space between the back surface supporting section 13c and the flexible substrate 11. Then, it is irradiated with UV rays to be hardened, whereby the space is sealed.

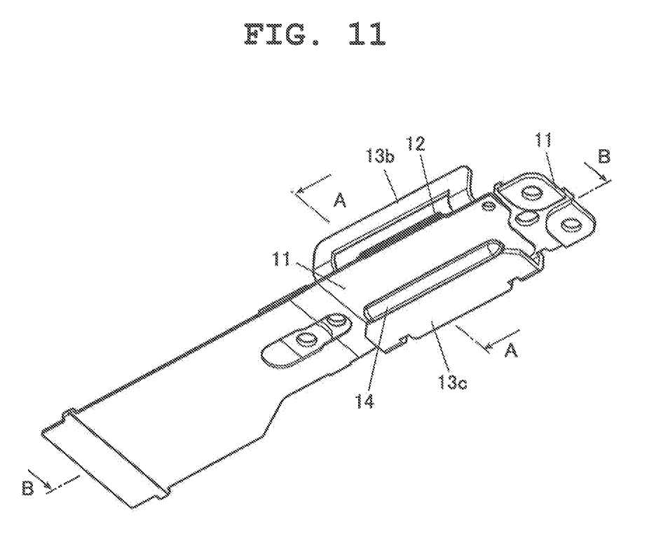

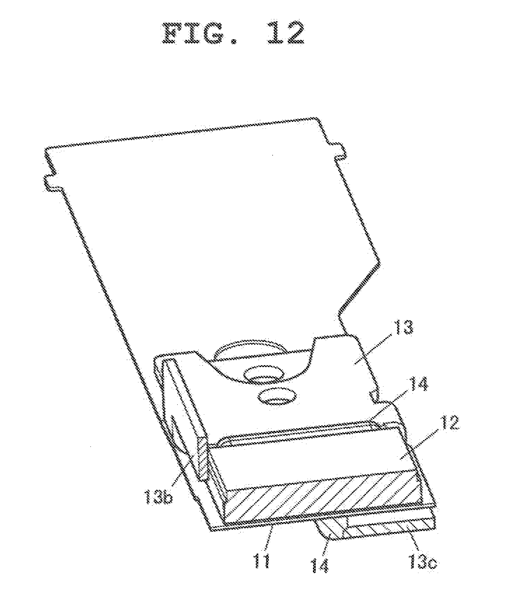

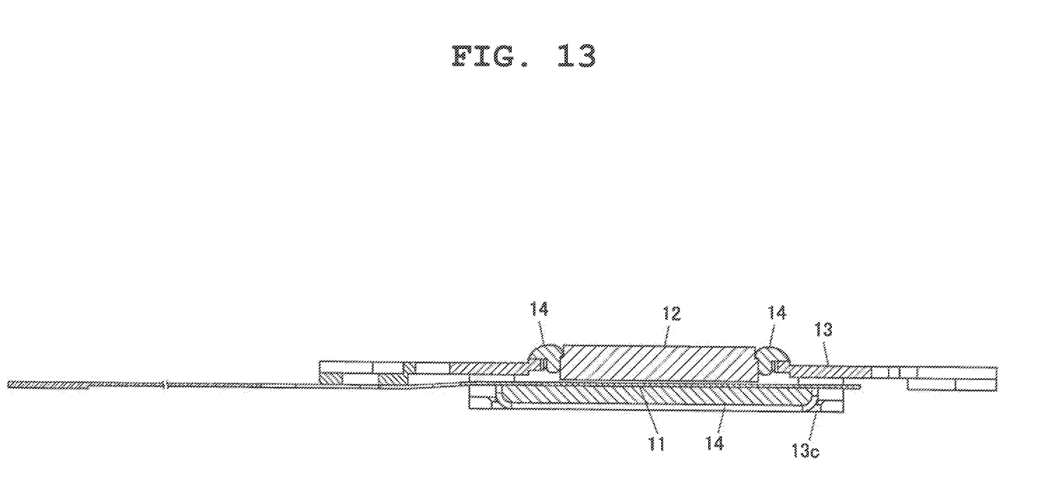

FIG. 11 shows the bonding of the plate 13 and the flexile substrate 11, viewed from the reverse side. FIG. 12 is a cross-sectional view taken along the arrow A-A line in FIG. 11, and FIG. 13 is a cross-sectional view taken along the arrow B-B line in FIG. 11.

As shown in the drawings, the image sensor 12 is supported by the back surface supporting section 13c of the plate 13 with the UV curing adhesive 14 therebetween. Therefore, the downward movement of the image sensor 12 in response to weight from above can be suppressed, and also the detachment of the image sensor 12 caused by an impact when dropped, etc. will be prevented.

Note that, as shown in FIG. 5, a portion of the elastic member 15 that is made of rubber is in contact with the periphery of the image sensor 12, and the optical filter 16 constituted by an optical low pass filter (OLPF) mounted in the lower portion of the lens unit 8 is arranged on top of this elastic member 15.

In the camera according to the above-described embodiment, the back surface supporting section 13c for supporting the image sensor 12 is provided to the plate 13. Therefore, even when force from the lens unit 8 placed in contact with the optical filter 16 is applied via the elastic member 15 to the image sensor 12 wherein both side surface sections are bonded to the plate 13 by the adhesive 14, the image sensor 12 will be prevented from being detached from the plate 13.

### Variation Example

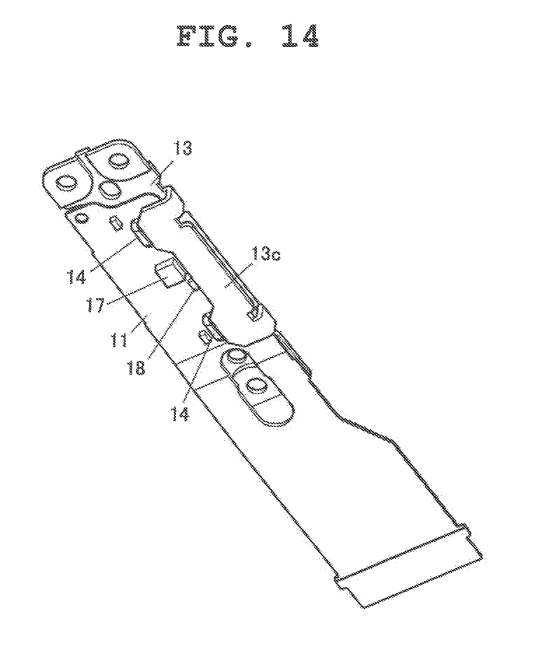

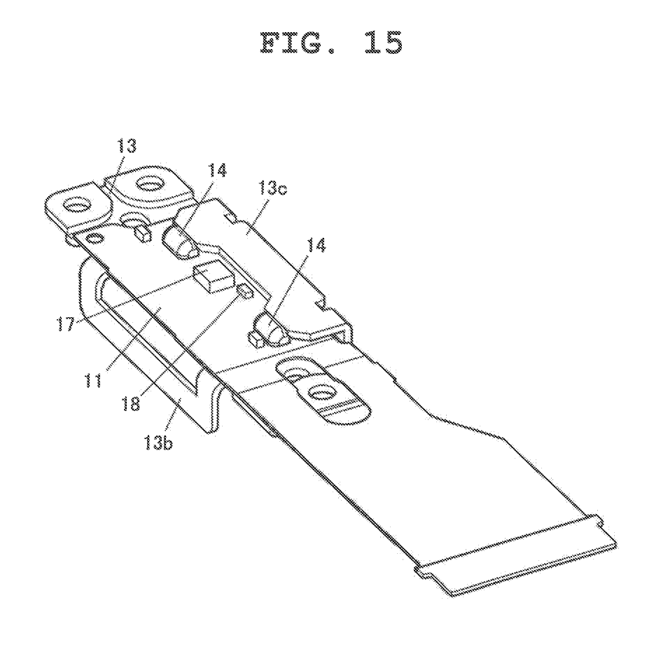

FIG. 14 and FIG. 15 show a variation example of the back surface supporting section 13c. As shown in the FIG. 14 and FIG. 15, in a case where other electronic components 17 and 18 are mounted substantially in the center of the back surface of the flexible substrate 11, and the back surface supporting section 13c of the plate 13, which has a linear shape, cannot be mounted as described because of them, the back surfaces supporting section 13c is formed in concavo-convex shape so as to circumvent the other electronic components 17 and 18 mounted substantially in the center.

Then, in the convex portions of the back surface supporting section 13c formed on the sides in a manner to circumvent the other electronic components 17 and 18, the spaces between the back surface supporting section 13c and the flexible substrate 11 are separately coated and filled with the UV curing adhesive 14. This UV curing adhesive 14 is then irradiated with UV rays to be hardened, and whereby the spaces are sealed.

### Other Variation Examples

In the above-described embodiment, the electronic device to which the present invention has been applied is a camera. However, the present invention is not limited thereto. The electronic device may be a mobile phone including a camera, etc.

In addition, the electronic component is not limited to the image sensor and may be any component that is substantially plate shaped.

Moreover, the shapes and the like of the electronic component, the supporting member, the opening, the back surface supporting section, the elastic member, and the module may be discretionarily changed, and the specific structural details and the like may be changed accordingly.

While the present invention has been described with reference to the preferred embodiments, it is intended that the invention be not limited by any of the details of the description therein but includes all the embodiments which fall within the scope of the appended claims.

What is claimed is:

1. A mounting structure for an electronic component comprising:
a substantially plate-shaped electronic component; and
a supporting member having an opening on a side surface section for bonding and supporting the substantially plate-shaped electronic component;
wherein the substantially plate-shaped electronic component is inserted into the opening from a front surface section side, and a back surface supporting section for supporting the substantially plate-shaped electronic component from a back surface section thereof is formed in the supporting member.

2. The mounting structure for an electronic component according to claim 1, wherein the substantially plate-shaped electronic component is sealed to the back surface supporting section of the supporting member by an adhesive.

3. The mounting structure for an electronic component according to claim 1, wherein the substantially plate-shaped electronic component is mounted on a flexible substrate, and the supporting member supports altogether the substantially plate-shaped electronic component and the flexible substrate.

4. The mounting structure for an electronic component according to claim 1, further comprising:
a module connected to the supporting member in a fixed manner;
wherein the substantially plate-shaped electronic component is an image sensor, and the module is a lens unit.

5. The mounting structure for an electronic component according to claim 4, wherein the lens unit includes an optical filter, and a front surface section of the imaging sensor is pressure-bonded to the optical filter via an elastic member.

6. An electronic device having the mounting structure according to claim 1.
